(19) United States
(12) Patent Application Publication
(10) Pub. No.: US 2021/0233979 A1
(43) Pub. Date: Jul. 29, 2021

(54) DISPLAY SUBSTRATE, DISPLAY APPARATUS, METHOD OF FABRICATING DISPLAY SUBSTRATE

(71) Applicants: Chengdu BOE Optoelectronics Technology Co., Ltd., Chengdu, Sichuan (CN); BOE Technology Group Co., Ltd., Beijing (CN)

(72) Inventors: Guoqiang Ma, Beijing (CN); Xucong Wang, Beijing (CN); Jingyi Feng, Beijing (CN); Peng Xu, Beijing (CN); Guoqiang Tang, Beijing (CN); Kuo Sun, Beijing (CN); Yangpeng Wang, Beijing (CN); Jianpeng Wu, Beijing (CN)

(73) Assignees: Chengdu BOE Optoelectronics Technology Co., Ltd., Chengdu, Sichuan (CN); BOE Technology Group Co., Ltd., Beijing (CN)

(21) Appl. No.: 16/753,440

(22) PCT Filed: Apr. 15, 2019
(86) PCT No.: PCT/CN2019/082683

§ 371 Date: Apr. 3, 2020

(51) Int. Cl. H01L 27/32; H01L 51/52; H01L 51/56

(52) U.S. Cl. CPC H01L 27/3246; H01L 51/5228; H01L 51/56; H01L 51/5212; H01L 27/3262; H01L 27/3258

(57) ABSTRACT

A display substrate is provided. The display substrate includes a plurality of subpixels configured to emit light for image display; and a plurality of auxiliary subpixels that are not light emitting. The display substrate in a region of the plurality of auxiliary subpixels includes a first auxiliary electrode layer on the base substrate and including a plurality of first auxiliary cathodes respectively in the plurality of auxiliary subpixels; and a second auxiliary electrode layer including a plurality of second auxiliary cathodes respectively in the plurality of auxiliary subpixels, the second auxiliary electrode layer being on a side of the first insulating layer away from the first auxiliary electrode layer. A respective one of the plurality of first auxiliary cathodes and a respective one of the plurality of second auxiliary cathodes are electrically connected to a unitary cathode layer of the plurality of light emitting elements.

### TECHNICAL FIELD

The present invention relates to display technology, more particularly, to a display substrate, a display apparatus, and a method of fabricating a display substrate.

### BACKGROUND

Organic light emitting diode (OLED) display apparatuses are self-emissive devices, and do not require backlights. OLED display apparatuses also provide more vivid colors and a larger color gamut as compared to the conventional liquid crystal display (LCD) apparatuses. Further, OLED display apparatuses can be made more flexible, thinner, and lighter than a typical LCD apparatus.

An OLED display apparatus typically includes an anode, an organic layer including an organic light emitting layer, and a cathode. OLEDs can either be a bottom-emission type OLED or a top-emission type OLED In bottom-emission type OLEDs, the light is extracted from an anode side. In bottom-emission type OLEDs, the anode is generally transparent, while a cathode is generally reflective. In a top-emission type OLED, light is extracted from a cathode side. In the top-emission type OLED, the cathode is optically transparent, while the anode is reflective.

### SUMMARY

In one aspect, the present invention provides a display substrate, comprising a plurality of subpixels configured to emit light for image display; and a plurality of auxiliary subpixels that are not light emitting; wherein the display substrate in a region of the plurality of subpixels comprises a base substrate; a plurality of thin film transistors respectively in the plurality of subpixels and on the base substrate; and a plurality of light emitting elements respectively in the plurality of subpixels and on a side of the plurality of thin film transistors away from the base substrate, the plurality of light emitting elements being respectively electrically connected to the plurality of thin film transistors; wherein the display substrate in a region of the plurality of auxiliary subpixels comprises a first auxiliary electrode layer on the base substrate and comprising a plurality of first auxiliary cathodes respectively in the plurality of auxiliary subpixels; a first insulating layer on a side of the first auxiliary electrode layer away from the base substrate; and a second auxiliary electrode layer comprising a plurality of second auxiliary cathodes respectively in the plurality of auxiliary subpixels, the second auxiliary electrode layer being on a side of the first insulating layer away from the first auxiliary electrode layer; wherein a respective one of the plurality of first auxiliary cathodes and a respective one of the plurality of second auxiliary cathodes are electrically connected to a unitary cathode layer of the plurality of light emitting elements

Optionally, the display substrate further comprises an anode layer on a side of the first insulating layer away from the base substrate; wherein the anode layer comprises a plurality of anodes, a respective one of the plurality of anodes being in a respective one of the plurality of light emitting elements.

Optionally, the second auxiliary electrode layer and the anode layer are in a same layer and comprise a came material; and a respective one of the plurality of second auxiliary cathodes electrically connects the respective one of the plurality of first auxiliary cathodes to the unitary cathode layer of the plurality of light emitting elements.

Optionally, the respective one of the plurality of second auxiliary cathodes extends through the first insulating layer to electrically connect to a respective one of the plurality of first auxiliary cathodes in a respective one of the plurality of auxiliary subpixels; and an orthographic projection of the respective one of the plurality of second auxiliary cathodes on the base substrate at least partially overlaps with an orthographic projection of the respective one of the plurality of first auxiliary cathodes on the base substrate.

Optionally, the display substrate further comprises a pixel definition layer for defining a plurality of subpixel apertures respectively in the plurality of subpixels and a plurality of auxiliary subpixel apertures respectively in the plurality of auxiliary subpixels.

Optionally, the unitary cathode layer extends into a respective one of the plurality of auxiliary subpixel apertures to connect to the respective one of the plurality of second auxiliary cathodes.

Optionally, the display substrate further comprises an organic functional layer between the anode layer and the unitary cathode layer and in the plurality of subpixel apertures; wherein the organic functional layer is absent in the plurality of auxiliary subpixel apertures.

Optionally, the display substrate further comprises a source-drain electrode layer comprising a plurality of source electrodes respectively for the plurality of thin film transistors and a plurality of drain electrodes respectively for the plurality of thin film transistors; and a second insulating layer on a side of the source-drain electrode layer away from the base substrate; wherein the first auxiliary electrode layer is on a side of the second insulating layer away from the source-drain electrode layer.

Optionally, the display substrate further comprises a source-drain electrode layer comprising a plurality of source electrodes respectively for the plurality of thin film transistors and a plurality of drain electrodes respectively for the plurality of thin film transistors; wherein the first auxiliary electrode layer and the source-drain electrode layer are in a same layer and comprise a same material.

Optionally, the first auxiliary electrode layer comprises a metallic material.

Optionally, the second auxiliary electrode layer and the anode layer comprise an oxide semiconductor material; and the first auxiliary electrode layer comprises a metallic material

Optionally, the plurality of auxiliary subpixels are absent of any light emitting elements and thin film transistors.

Optionally, the display substrate comprises a plurality of pixels, a respective one of the plurality of pixels comprising a respective one of a plurality of first subpixels, a respective one of a plurality of second subpixels, a respective one of a plurality of third subpixels, and a respective one of the plurality of auxiliary subpixels; the plurality of subpixels are arranged as a plurality of first columns of subpixels and a plurality of second columns of subpixels alternately arranged along a row direction; a respective one of the plurality of first columns of subpixels comprises a plurality of first subpixels and a plurality of second subpixels alternately arranged along a column direction; a respective one of the plurality of second columns of subpixels comprises a plurality of third subpixels and a plurality of auxiliary subpixels alternately arranged along the column direction; and a respective one of the plurality of auxiliary subpixels in a respective one of the plurality of second columns of subpixels is aligned, along the row direction, with an inter-subpixel region between a respective one of the plurality of first subpixels and a respective one of the plurality of second subpixels in an adjacent column of the plurality of first columns of subpixels.

In another aspect, the present invention provides a display apparatus, comprising the display substrate described herein, and one or more integrated circuits connected to the display substrate.

In another aspect, the present invention provides a method of fabricating a display substrate, comprising forming a plurality of subpixels configured to emit light for image display; and forming a plurality of auxiliary subpixels that are not light emitting; wherein forming the plurality of subpixels comprises forming a plurality of thin film transistors respectively in the plurality of subpixels and on the base substrate; and forming a plurality of light emitting elements respectively in the plurality of subpixels and on a side of the plurality of thin film transistors away from the base substrate, the plurality of light emitting elements farmed to be respectively electrically connected to the plurality of thin film transistors; wherein forming the plurality of auxiliary subpixels comprises forming a first auxiliary electrode layer on the base substrate, the first auxiliary electrode layer formed to comprise a plurality of first auxiliary cathodes respectively in the plurality of auxiliary subpixels; forming a first insulating layer on a side of the first auxiliary electrode layer away from the base substrate; and forming a second auxiliary electrode layer comprising a plurality of second auxiliary cathodes respectively in the plurality of auxiliary subpixels, the second auxiliary electrode layer formed on a side of the first insulating layer away from the first auxiliary electrode layer; wherein a respective one of the plurality of first auxiliary cathodes and a respective one of the plurality of second auxiliary cathodes are formed to be electrically connected to a unitary cathode layer of the plurality of light emitting elements

Optionally, subsequent to forming the plurality of thin film transistors, the method further comprises forming an anode layer on a side of the first insulating layer away from the base substrate; wherein forming the anode layer comprises forming a plurality of anodes, a respective one of the plurality of anodes formed in a respective one of the plurality of light emitting elements.

Optionally, the second auxiliary electrode layer and the anode layer are formed in a same layer and using a same material in a same patterning process with a same mask plate; and a respective one of the plurality of second auxiliary cathodes is formed to electrically connects the respective one of the plurality of first auxiliary cathodes to the unitary cathode layer of the plurality of light emitting elements.

Optionally, the method further comprises forming a pixel definition layer for defining a plurality of subpixel apertures respectively in the plurality of subpixels and a plurality of auxiliary subpixel apertures respectively in the plurality of auxiliary subpixels.

Optionally, subsequent to forming the pixel definition layer, the method further comprises depositing an organic material layer in the plurality of subpixel apertures and in the plurality of auxiliary subpixel apertures; and ashing the organic material layer in the plurality of auxiliary subpixel apertures to completely remove any organic functional material therein to expose the plurality of second auxiliary cathodes.

Optionally, subsequent to ashing the organic material layer in the plurality of auxiliary subpixel apertures, the method further comprises depositing a conductive material layer in an open mask process, thereby forming the unitary cathode layer.

### BRIEF DESCRIPTION OF THE FIGURES

The following drawings are merely examples for illustrative purposes according to various disclosed embodiments and are not intended to limit the scope of the present invention.

FIG. 1 is a schematic diagram illustrating the structure of a display substrate in some embodiments according to the present disclosure.

FIG. 2 is a schematic diagram illustrating the structure of a display substrate in some embodiments according to the present disclosure.

FIG. 3 is a schematic diagram illustrating the structure of a display substrate in some embodiments according to the present disclosure.

FIGS. 4A to 4E illustrate a method of fabricating a display substrate in some embodiments according to the present disclosure.

FIG. 5A and FIG. 5B illustrate mask plates that can be used for aching the second portion of the organic material layer in the plurality of auxiliary subpixel apertures.

FIG. 6 is a schematic diagram illustrating a pixel arrangement in a display substrate in some embodiments according to the present disclosure.

FIG. 7 is a schematic diagram illustrating a pixel arrangement in a display substrate in some embodiments according to the present disclosure.

FIG. 8 illustrates a mask plate for forming a plurality of subpixels in some embodiments according to the present disclosure.

### DETAILED DESCRIPTION

The disclosure will now be described more specifically with reference to the following embodiments. It is to be noted that the following descriptions of some embodiments are presented herein for purpose of illustration and description only. It is not intended to be exhaustive or to be limited to the precise form disclosed.

In organic light emitting diode display panel, a layer of cathode is deposited in an open mask process on the display panel. Thus, an IR drop exists across different regions of the cathode across the display panel. In order to enhance light transmittance, typically the cathode is made as a thin layer, increasing the resistance of the cathode. The increase in the IR drop leads to non-uniformity of voltage levels across various regions of the cathode, resulting in non-uniformity of display illuminance in the display panel.

Accordingly, the present disclosure provides, inter alia, a display substrate, a display apparatus, and a method of fabricating a display substrate that substantially obviate one or more of the problems due to limitations and disadvantages of the related art. In one aspect, the present disclosure provides a display substrate. In some embodiments, the display substrate includes a plurality of subpixels configured to emit light for image display and a plurality of auxiliary subpixels that are not light emitting. In some embodiments, the display substrate in a region of the plurality of subpixels includes a base substrate; a plurality of thin film transistors respectively in the plurality of subpixels and on the base substrate; and a plurality of light emitting elements respectively in the plurality of subpixels and on a side of the plurality of thin film transistors away from the base substrate, the plurality of light emitting elements being respectively electrically connected to the plurality of thin film transistors. In some embodiments, the display substrate in a region of the plurality of auxiliary subpixels includes a first auxiliary electrode layer on the base substrate and including a plurality of first auxiliary cathodes respectively in the plurality of auxiliary subpixels; a first insulating layer on a side of the first auxiliary electrode layer away from the base substrate; and a second auxiliary electrode layer including a plurality of second auxiliary cathodes respectively in the plurality of auxiliary subpixels, the second auxiliary electrode layer being on a side of the first insulating layer away from the first auxiliary electrode layer. Optionally, a respective one of the plurality of the first auxiliary cathodes and a respective one of the plurality of second auxiliary cathodes are electrically connected to a unitary cathode layer of the plurality of light emitting elements.

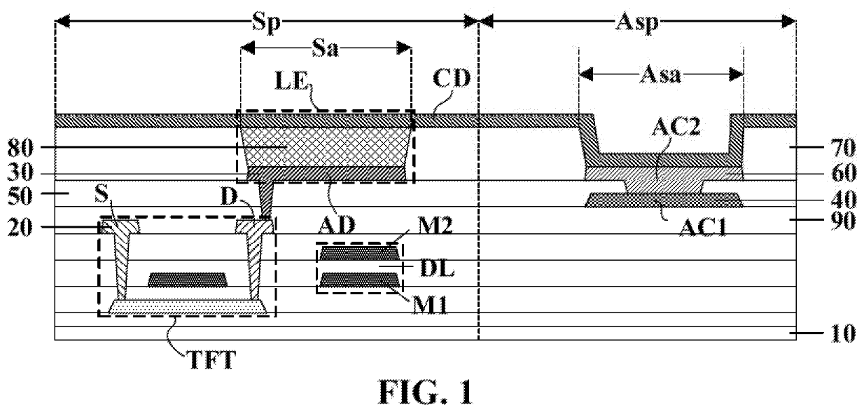

FIG. 1 is a schematic diagram illustrating the structure of a display substrate in some embodiments according to the present disclosure. Referring to FIG. 1, the display substrate has a plurality of subpixels Sp and a plurality of auxiliary subpixels Asp. The display substrate includes a base substrate 10, a plurality of thin film transistors TFT respectively in the plurality of subpixels Sp and on the base substrate 10, and a plurality of light emitting elements LE respectively in the plurality of subpixels Sp and on a side of the plurality of thin film transistors TFT away from the base substrate 10. The plurality of light emitting elements LE are respectively electrically connected to the plurality of thin film transistors TFT.

Various appropriate light emitting elements may be used in the present display substrate. Examples of appropriate light emitting elements include organic light emitting diodes, quantum dots light emitting diodes, and micro light emitting diodes.

In some embodiments, the display substrate includes a source-drain electrode layer 20, including a plurality of source electrodes S respectively for the plurality of thin film transistors TFT and a plurality of drain electrodes D respectively for the plurality of thin film transistors TFT.

In some embodiments, the display substrate includes an anode layer 30, including a plurality of anodes AD, a respective one of the plurality of anodes AD being in a respective one of the plurality of light emitting elements LE.

In some embodiments, a respective one of the plurality of light emitting elements LE in a respective one of the plurality of subpixels Sp is electrically connected to a respective one of the plurality of drain electrodes D in a respective one of the plurality of thin film transistors TFT in the respective one of the plurality of subpixels Sp, thereby electrically connecting the respective one of the plurality of light emitting elements LE to the respective one of the plurality of thin film transistors TFT.

Referring to FIG. 1 again, the display substrate in some embodiments further includes a first auxiliary electrode layer 40 including a plurality of first auxiliary cathodes AC1 respectively in the plurality of auxiliary subpixels Asp, the first auxiliary electrode layer 40 configured to receive a common voltage.

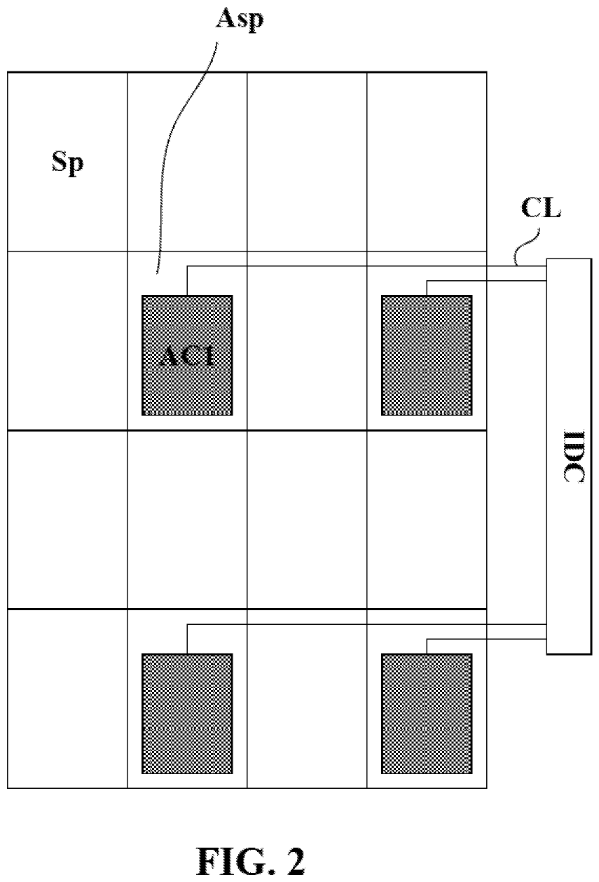

FIG. 2 is a schematic diagram illustrating the structure of a display substrate in some embodiments according to the present disclosure. Referring to FIG. 2, the display substrate in some embodiments has a plurality of subpixels Sp and a plurality of auxiliary subpixels Asp. The display substrate includes a plurality of first auxiliary cathodes AC1 respectively in the plurality of auxiliary subpixels Asp. In some embodiments, the display substrate further includes a plurality of common voltage signal lines CL respectively electrically connected to the plurality of first auxiliary cathodes AC1 and configured to provide a common voltage to the plurality of first auxiliary cathodes AC1. In one example, the display substrate further includes a driver circuit IDC for providing the common voltage to the plurality of common voltage signal lines CL.

Optionally, the plurality of common voltage signal lines CL are connected to a ground.

Optionally, the plurality of common voltage signal lines CL and the plurality of first auxiliary cathodes AC1 are in a same layer and made of a same material. As used herein, the term “same layer” refers to the relationship between the layers simultaneously formed in the same step. In one example, the plurality of common voltage signal lines CL and the plurality of first auxiliary cathodes AC1 are in a same layer when they are formed as a result of one or more steps of a same patterning process performed in a same layer of material. In another example, the plurality of common voltage signal lines CL and the plurality of first auxiliary cathodes AC1 can be formed in a same layer by simultaneously performing the step of forming the plurality of common voltage signal lines CL and the step of forming the plurality of first auxiliary cathodes AC1. The term “same layer” does not always mean that the thickness of the layer or the height of the layer in a cross-sectional view is the same.

Optionally, the plurality of common voltage signal lines CL and the plurality of first auxiliary cathodes AC1 are in different layers, for example, spaced apart by an insulating layer. A respective one of the plurality of common voltage signal lines CL is electrically connected to a respective one of the plurality of first auxiliary cathodes AC1 through a via extending through the insulating layer.

The display substrate may have any appropriate ratio between a total number of the plurality of subpixels Sp and a total number of the plurality of auxiliary subpixels Asp. FIG. 2 shows a non-limiting example in which a ratio between the total number of the plurality of subpixels Sp and the total number of the plurality of auxiliary subpixels Asp is 3:1, e.g., each pixel of the display substrate includes three subpixels and one auxiliary subpixel. Optionally, the ratio between the total number of the plurality of subpixels Sp and the total number of the plurality of auxiliary subpixels Asp is in a range of 300:1 to 3:1, e.g., 300:1 to 200:1, 200:1 to 100:1, 100:1 to 50:1, 50:1 to 25:1, 25:1 to 10:1, 10:1 to 6:1, and 6:1 to 3:1. Optionally, the ratio between the total number of the plurality of subpixels Sp and the total number of the plurality of auxiliary subpixels Asp is greater than 300:1.

Optionally, a respective one of the plurality of auxiliary subpixels Asp has a size (e.g., an occupied area) substantially the same as that of a respective one of the plurality of subpixels Sp. As used herein, the term “substantially the same” refers to a difference between two values not exceeding 10% of a base value (e.g., one of the two values), e.g., not exceeding 8%, not exceeding 6%, not exceeding 4%, not exceeding 2%, not exceeding 1%, not exceeding 0.5%, not exceeding 0.1%, not exceeding 0.05%, and not exceeding 0.01%, of the base value. Optionally, the respective one of the plurality of auxiliary subpixels Asp has a size smaller than that of the respective one of the plurality of subpixels Sp. In one example, the respective one of the plurality of auxiliary subpixels Asp has a size approximately half, or less than half, of that of the respective one of the plurality of subpixels Sp.

Various appropriate electrode materials and various appropriate fabricating methods may be used for making the first auxiliary electrode layer 40. For example, an electrode material may be deposited on the substrate (e.g., by sputtering, vapor deposition, solution coating or spin coating); and patterned (e.g., by lithography such as a wet etching process) to form the plurality of first auxiliary cathodes AC1. Examples of appropriate electrode materials for making the first auxiliary electrode layer 40 include, but are not limited to, various metal materials such as molybdenum, aluminum silver, chromium, tungsten, titanium, tantalum, copper, and alloys or laminates containing the same; and various conductive metal oxides such as indium tin oxide. Optionally, the first auxiliary electrode layer 40 is made of a metallic material.

Referring to FIG. 1, the display substrate in some embodiments further includes a first insulating layer 50 on a side of the first auxiliary electrode layer 40 away from the base substrate 10, and an anode layer 30 on a side of the first insulating layer 50 away from the base substrate 10. The anode layer 30 includes a plurality of anodes AD, a respective one of the plurality of anodes AD being in a respective one of the plurality of light emitting elements LE.

Various appropriate materials and various appropriate fabricating methods may be used to make the anode layer 30. For example, a conductive material may be deposited by a plasma-enhanced chemical vapor deposition (PECVD) process or a sputtering process, e.g., a magnetron sputtering process. The deposited conductive material layer is then patterned, e.g., by a lithographic process. Examples of appropriate conductive materials for making the anode layer 30 include, but are not limited to, various metal materials such as molybdenum, aluminum, silver, chromium, tungsten, titanium, tantalum, copper, and alloys or laminates containing the same; and various conductive metal oxides such as indium tin oxide. Optionally, the anode layer 30 is made of an oxide semiconductor material

Referring to FIG. 1, in some embodiments, a respective one of the plurality of first auxiliary cathodes AC1 is electrically connected to a unitary cathode layer CD of the plurality of light emitting elements LE for transmitting the common voltage to the unitary cathode layer CD. In one specific embodiments, the display substrate further includes a second auxiliary electrode layer 60 including a plurality of second auxiliary cathodes AC2 respectively in the plurality of auxiliary subpixels Asp. The second auxiliary electrode layer 60 is on a side of the first insulating layer 50 away from the first auxiliary electrode layer 40. A respective one of the plurality of second auxiliary cathodes AC2 electrically connects the respective one of the plurality of first auxiliary cathodes AC1 to the unitary cathode layer CD of the plurality of light emitting elements. LE for transmitting the common voltage to the unitary cathode layer CD.

Various appropriate materials and various appropriate fabricating methods may be used to make the second auxiliary electrode layer 60. For example, a conductive material may be deposited by a plasma-enhanced chemical vapor deposition (PECVD) process or a sputtering process, e.g., a magnetron sputtering process. The deposited conductive material layer is then patterned, e.g., by a lithographic process. Examples of appropriate conductive materials for making the second auxiliary electrode layer 60 include, but are not limited to, various metal materials such as molybdenum, aluminum, silver, chromium, tungsten, titanium, tantalum, copper, and alloys or laminates containing the same; and various conductive metal oxides such as indium tin oxide. Optionally, the second auxiliary electrode layer 60 is made of an oxide semiconductor material.

Optionally, the second auxiliary electrode layer 60 and the anode layer 30 are in a same layer and comprise a same material.

Optionally, the respective one of the plurality of second auxiliary cathodes AC2 extends through the first insulating layer 50 (e.g., through a via extending through the first insulating layer 50) to electrically connect to a respective one of the plurality of first auxiliary cathodes AC1 in a respective one of the plurality of auxiliary subpixels Asp. Optionally, an orthographic projection of the respective one of the plurality of second auxiliary cathodes AC2 on the base substrate 10 at least partially overlaps with an orthographic projection of the respective one of the plurality of first auxiliary cathodes AC1 on the base substrate 10. In one example the unitary cathode layer CD extend into a respective one of a plurality of auxiliary subpixel apertures Asa to be in direct contact with the respective one of the plurality of second auxiliary cathodes AC2, and the respective one of the plurality of second auxiliary cathodes AC2 extends through the via extending through the first insulating layer 50 to be in direct contact with the respective one of the plurality of first auxiliary cathodes AC1.

Referring to FIG. 1, the display substrate in some embodiments further includes a pixel definition layer 70 for defining (e.g., by its lateral walls) a plurality of subpixel apertures Sa respectively in the plurality of subpixels Sp and a plurality of auxiliary subpixel apertures Asa respectively in the plurality of auxiliary subpixels Asp. Further, the display substrate in some embodiments includes an organic functional layer 80 between the anode layer 30 and the unitary cathode layer CD, and in the plurality of subpixel apertures Sa. The organic functional layer 80 is absent in the plurality of auxiliary subpixel apertures Asa, e.g., the organic functional layer 80 is limited in the plurality of subpixels Sp, and is absent in the plurality of auxiliary subpixels Asp.

In some embodiments, the organic functional layer 80 includes an organic light emitting layer. Various appropriate materials and various appropriate fabricating methods may be used to make the organic light emitting layer. For example, an organic light emitting material may be deposited by a plasma-enhanced chemical vapor deposition (PECVD) process or a coating process. Optionally, the organic light emitting layer may have a tingle layer structure. Optionally, the organic light emitting layer has a multi-layer structure and including multiple sub-layers.

In some embodiments the organic functional layer 80 further includes any one of the following layers: a hole transport layer, a hole injection layer, an electron transport layer, and an electron injection layer. Various appropriate materials and various appropriate fabricating methods may be used to make the hole transport layer. For example, a hole transport material may be deposited by a plasma-enhanced chemical vapor deposition (PECVD) process or a coating process. Examples of appropriate hole transport materials include N,N′-Bis-(1-naphthalenyl)-N,N′-bis-phenyl-(1,1′-biphenyl)-4,4′-diamine (NPB). Various appropriate materials and various appropriate fabricating methods may be used to make the electron transport layer. For example, an electron transport material may be deposited by a plasma-enhanced chemical vapor deposition (PECVD) process or a coating process. Optionally, the deposited electron transport material layer has a thickness in a range of approximately 5 nm to approximately 50 nm Examples of appropriate electron transport materials include 4,7-diphenyl-1,10-phenanthroline (Bphen).

Referring to FIG. 1, in some embodiments, the unitary cathode layer CD extends into a respective one of the plurality of auxiliary subpixel apertures Asa to connect to the respective one of the plurality of second auxiliary cathodes AC2, thereby receiving the common voltage signal from the respective one of the plurality of first auxiliary cathodes AC1 provided by the respective one of the plurality of common voltage signal lines.

The first auxiliary electrode layer 40 may be disposed in any appropriate layer. In some embodiments, and referring to FIG. 1, the display substrate includes a source-drain electrode layer 20 including a plurality of source electrodes S respectively for the plurality of thin film transistors TFT and a plurality of drain electrodes D respectively for the plurality of thin film transistors TFT. The display substrate further includes a second insulating layer 90 on a side of the source-drain electrode layer 20 away from the base substrate 10. Optionally, the first auxiliary electrode layer 40 is on a side of the second insulating layer 90 away from the source-drain electrode layer 20.

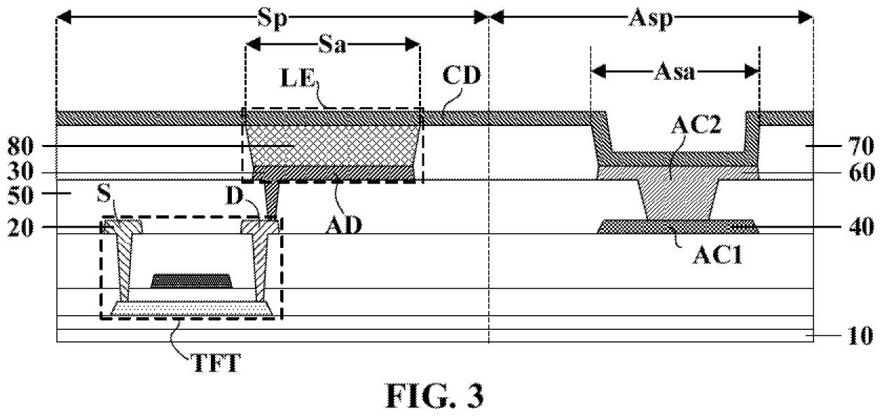

In some embodiments, the first auxiliary electrode layer 40 and the source-drain electrode layer 20 may be in a same layer. FIG. 3 is a schematic diagram illustrating the structure of a display substrate in some embodiments according to the present disclosure. Referring to FIG. 3, the first auxiliary electrode layer 40 and the source-drain electrode layer 20 may be in a same layer and may be made of a same material, e.g., a same metallic material. Optionally, the anode layer 30 and the second auxiliary electrode layer 60 are in a same layer and may be made of a same material, e.g., a same oxide semiconductor material. The first auxiliary electrode layer 40 and the second auxiliary electrode layer 60 are spaced apart from each other by the first insulating layer 50, and the anode layer 30 and the source-drain electrode layer 20 are spaced apart from each other by the first insulating layer 50. A respective one of the plurality of anodes AD extends through the first insulating layer 50 to electrically connect to a respective one of the plurality of drain electrodes D. A respective one of the plurality of second auxiliary cathodes AC2 extends through the first insulating layer 50 to electrically connect to a respective one of the plurality of first auxiliary cathodes AC1.

Optionally, the plurality of auxiliary subpixels Asp are absent of any light emitting elements and thin film transistors.

Optionally, and referring to FIG. 1, the display substrate further includes a storage capacitor including a first electrode M1, a dielectric layer DL, and a second electrode M2.

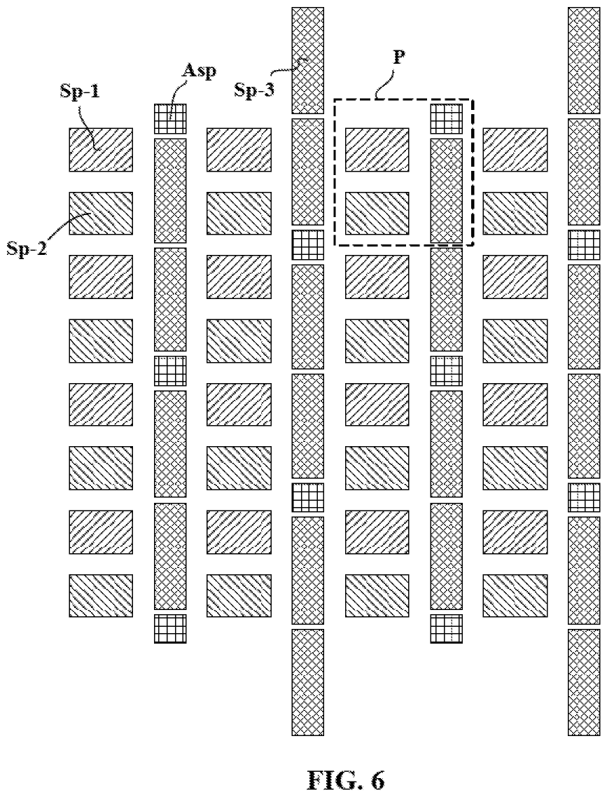

FIG. 6 is a schematic diagram illustrating a pixel arrangement in a display substrate in some embodiments according to the present disclosure. Refining to FIG. 6, the display substrate includes a plurality of pixels P. A respective one of the plurality of pixels P includes a respective one of a plurality of first subpixels Sp-1 (e.g., a red subpixel), a respective one of a plurality of second subpixels Sp-2 (e.g., a green subpixel), and a respective one of a plurality of third subpixels Sp-3 (e.g., a blue subpixel). Optionally, the respective one of the plurality of pixels P further includes a respective one of the plurality of auxiliary subpixels Asp. Optionally, each of the plurality of pixels P includes a first subpixel Sp-1 (e.g., a red subpixel), a second subpixel Sp-2 (e.g., a green subpixel), a third subpixel Sp-3 (e.g., a blue subpixel), and one of the plurality of auxiliary subpixels Asp.

In some embodiments, the display substrate includes a plurality of first columns of subpixels and a plurality of second columns of subpixels alternately arranged along a row direction. A respective one of the plurality of first columns of subpixels includes a plurality of first subpixels Sp-1 and a plurality of second subpixels Sp-2 alternately arranged along a column direction. A respective one of the plurality of second columns of subpixels includes a plurality of third subpixels Sp-3 and a plurality of auxiliary subpixels Asp alternately arranged along the column direction. Optionally, a respective one of the plurality of auxiliary subpixels Asp in a respective one of the plurality of second columns of subpixels is aligned, along the row direction, with an inter-subpixel region between a respective one of the plurality of first subpixels Sp-1 and a respective one of the plurality of second subpixels Sp-2 in an adjacent column of the plurality of first columns of subpixels. As used herein, the term “aligned with” used in connection with the plurality of auxiliary subpixels Asp and the inter-subpixel region refers to that a mid-line of the inter-subpixel region, e.g., along the row direction, intersects with the respective one of the plurality of auxiliary subpixels Asp in the respective one of the plurality of second columns of subpixels. Optionally, the mid-line of the inter-subpixel region along the row direction intersects with a mid-line of the respective one of the plurality of auxiliary subpixels Asp in the respective one of the plurality of second columns of subpixels, with a certain margin of inaccuracy or error tolerated. Optionally, edge lines of the inter-subpixel region along the row direction respectively intersect with the respective one of the plurality of auxiliary subpixels Asp in the respective one of the plurality of second columns of subpixels. Optionally, edge lines of the respective one of the plurality of auxiliary subpixels Asp in the respective one of the plurality of second columns of subpixels, along the row direction, respectively intersect with the respective one of the plurality of first subpixels Sp-1 and the respective one of the plurality of second subpixels Sp-2 in an adjacent column of the plurality of first columns of subpixels.

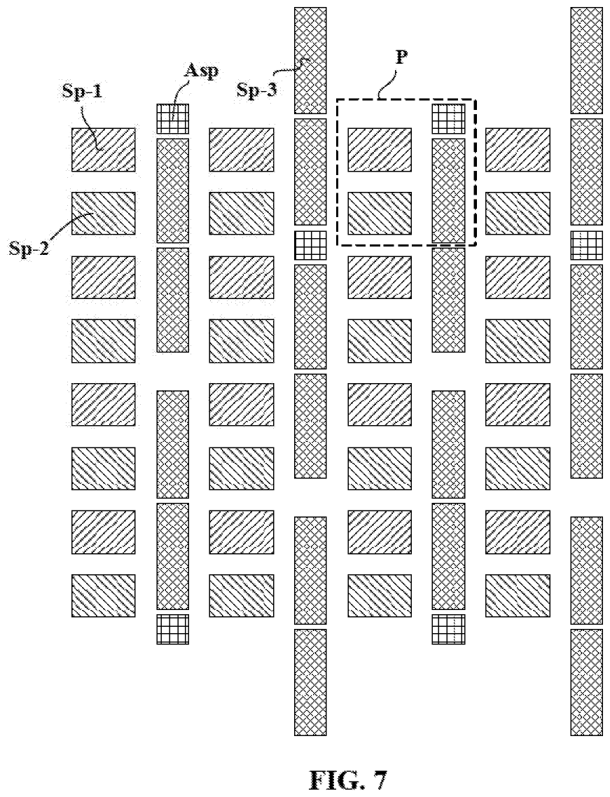

FIG. 7 is a schematic diagram illustrating a pixel arrangement in a display substrate in some embodiments according to the present disclosure. Referring to FIG. 7, the display substrate has a lower distribution density of the plurality of auxiliary subpixels Asp as compared to the display substrate in FIG. 6.

In another aspect, the present disclosure provides a method of fabricating a display substrate. In some embodiments, the method includes forming a plurality of subpixels to emit light for image display and forming a plurality of auxiliary subpixels that are not light emitting. In some embodiments, the step of forming the plurality of subpixels includes forming a plurality of thin film transistors respectively in the plurality of subpixels and on the base substrate; and forming a plurality of light emitting elements respectively in the plurality of subpixels and on a side of the plurality of thin film transistors away from the base substrate, the plurality of light emitting elements formed to be respectively electrically connected to the plurality of thin film transistors. In some embodiments, the step of forming the plurality of auxiliary subpixels includes forming a first auxiliary electrode layer on the base substrate, the first auxiliary electrode layer formed to include a plurality of first auxiliary cathodes respectively in the plurality of auxiliary subpixels; forming a first insulating layer on a side of the first auxiliary electrode layer away from the base substrate; and forming a second auxiliary electrode layer including a plurality of second auxiliary cathodes respectively in the plurality of auxiliary subpixels, the second auxiliary electrode layer formed on a side of the first insulating layer away from the first auxiliary electrode layer. Optionally, a respective one of the plurality of first auxiliary cathodes and a respective one of the plurality of second auxiliary cathodes are formed to be electrically connected to a unitary cathode layer of the plurality of light emitting elements.

In some embodiments, subsequent to forming the plurality of thin film transistors, the method further includes forming a first insulating layer on a side of the first auxiliary electrode layer away from the base substrate; and forming an anode layer on a side of the first insulating layer away from the base substrate. Optionally, forming the anode layer includes forming a plurality of anodes, a respective one of the plurality of anodes formed in a respective one of the plurality of light emitting elements.

In some embodiments, the method further includes forming a second auxiliary electrode layer including a plurality of second auxiliary cathodes respectively in the plurality of auxiliary subpixels, the second auxiliary electrode layer formed on a side of the first insulating layer away from the first auxiliary electrode layer. Optionally, the second auxiliary electrode layer and the anode layer are formed in a same layer and using a same material in a same patterning process with a came mask plate. Optionally, a respective one of the plurality of second auxiliary cathodes is formed to electrically connects the respective one of the plurality of first auxiliary cathodes to the unitary cathode layer of the plurality of light emitting elements for transmitting the common voltage to the unitary cathode layer.

In some embodiments, the respective one of the plurality of second auxiliary cathodes is formed to extend through the first insulating layer to electrically connect to a respective one of the plurality of first auxiliary cathodes in a respective one of the plurality of auxiliary subpixels. Optionally, an orthographic projection of the respective one of the plurality of second auxiliary cathodes on the base substrate at least partially overlaps with an orthographic projection of the respective one of the plurality of first auxiliary cathodes on the base substrate.

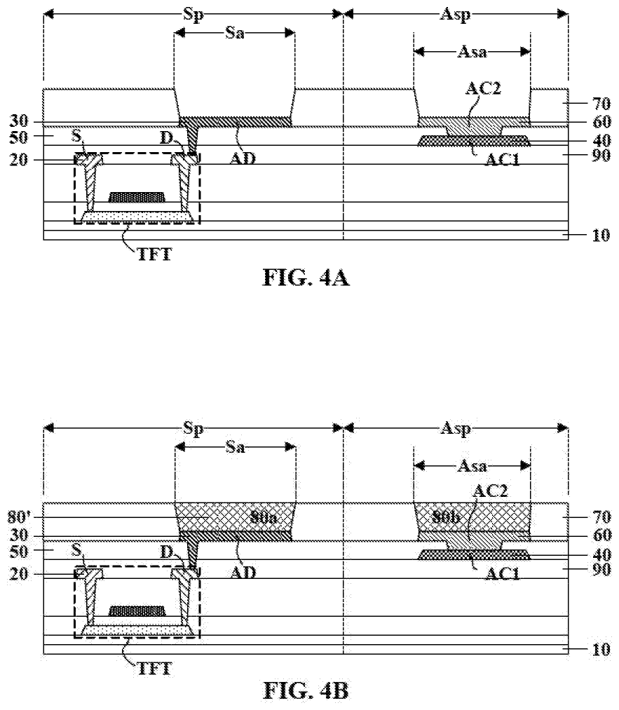

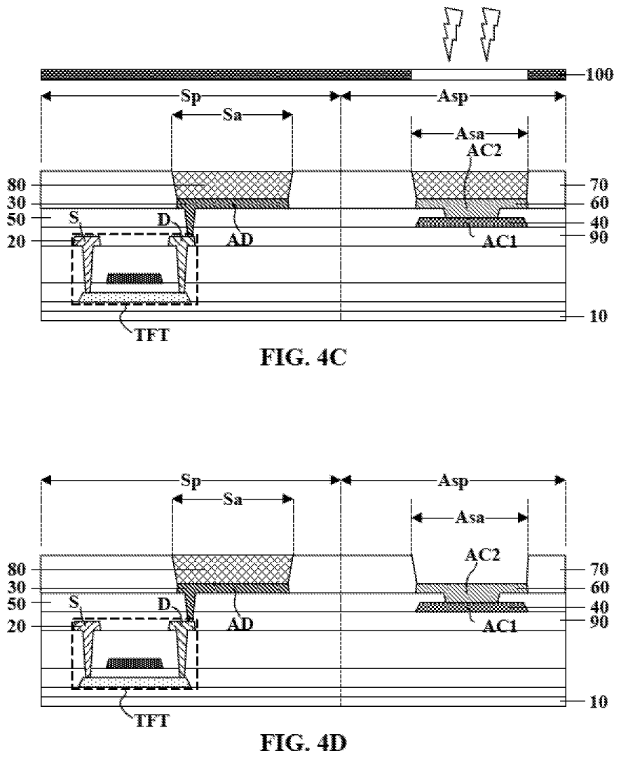

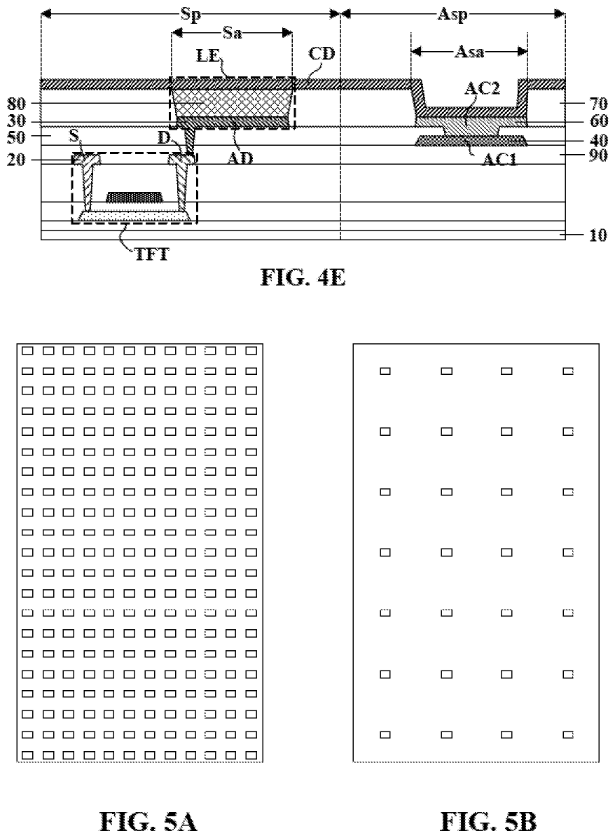

FIGS. 4A to 4E illustrate a method of fabricating a display substrate in some embodiments according to the present disclosure. Referring to FIG. 4A, the method further includes forming a pixel definition layer 70 defining a plurality of subpixel apertures Sa respectively in the plurality of subpixels Sp and a plurality of auxiliary subpixel apertures Asa respectively in the plurality of auxiliary subpixels Asp. In one example, a pixel definition material is deposited on the substrate, followed by patterning the pixel definition material to form the plurality of subpixel apertures Sa respectively in the plurality of subpixels Sp and the plurality of auxiliary subpixel apertures Asa respectively in the plurality of auxiliary subpixels Asp. In another example a respective one of the plurality of anodes AD is at the bottom of a respective one of the plurality of subpixel apertures Sa, and a respective one of the plurality of second auxiliary cathodes AC2 is at the bottom of a respective one of the plurality of auxiliary subpixel apertures Asa.

Referring to FIG. 4B, subsequent to forming the pixel definition layer 70, the method further includes depositing an organic material layer 80′ in the plurality of subpixel apertures Sa and in the plurality of auxiliary subpixel apertures Asa. The organic material layer 80′ is formed to include a first portion 80a in the plurality of subpixel apertures Sa and a second portion 80b in the plurality of auxiliary subpixel apertures Asa. The organic material layer 80′ may be formed to include an organic light emitting material layer. Optionally, the organic material layer 80′ is formed to further include any one of the following layers: a hole transport material layer, a hole injection material layer, an electron transport material layer, and an electron injection material layer.

In some embodiments, the method further includes removing the second portion 80b of the organic material layer 80′ in the plurality of auxiliary subpixel apertures Asa, so that the plurality of auxiliary subpixel apertures Asa are free of any organic light emitting materials or other organic functional materials. Referring to FIG. 4C and FIG. 4D, in some embodiments the step of removing the second portion 80b includes ashing the second portion 80b (i.e., the organic material layer 80′ in the plurality of auxiliary subpixel apertures Asa) to completely remove any organic functional material therein to expose the plurality of second auxiliary cathodes AC2. The ashing may be performed, for example, using a laser and a mask plate 100. The mask plate 100 includes light transmissive regions corresponding to the plurality of auxiliary subpixel apertures Asa, and the remainder region which is light blocking.

Referring to FIG. 4E, subsequent to aching the organic material layer in the plurality of auxiliary subpixel apertures Asa, the method further includes depositing a conductive material layer in an open mask process, thereby fanning the unitary cathode layer CD.

FIG. 5A and FIG. 5B illustrate mask plates that can be used for ashing the second portion of the organic material layer in the plurality of auxiliary subpixel apertures. The mask plate in FIG. 5A has a higher distribution density of light transmissive regions than that of the mask plate in FIG. 5B. In one example, the mask plate in FIG. 5A is used for making a display substrate having a 3:1 ratio between the total number of the plurality of subpixels Sp and the total number of the plurality of auxiliary subpixels Asp, e.g., each pixel of the display substrate includes three subpixels and one auxiliary subpixel. In another example, the mask plate in FIG. 5B is used for making a display substrate having a 12:1 ratio between the total number of the plurality of subpixels Sp and the total number of the plurality of auxiliary subpixels Asp, e.g., each four pixels of the display substrate includes twelve subpixels and one auxiliary subpixel.

In some embodiments, referring to FIG. 6 and FIG. 7, the method includes forming a plurality of pixels P. A respective one of the plurality of pixels P is formed to include a respective one of the plurality of first subpixels Sp-1 (e.g., a red subpixel), a respective one of the plurality of second subpixels Sp-2 (e.g., a green subpixel), and a respective one of the plurality of third subpixels Sp-3 (e.g., a blue subpixel). Optionally, the respective one of the plurality of pixels P is further formed to include a respective one of the plurality of auxiliary subpixels Asp. Optionally, referring to FIG. 6, each of the plurality of pixels P is formed to include a first subpixel Sp-1 (e.g., a red subpixel), a second subpixel Sp-2 (e.g., a green subpixel), a third subpixel Sp-3 (e.g., a blue subpixel), and one of the plurality of auxiliary subpixels Asp.

In some embodiments the method includes forming a plurality of first columns of subpixels and forming a plurality of second columns of subpixels alternately arranged along a row direction. A respective one of the plurality of first columns of subpixels is formed to include a plurality of first subpixels Sp-1 and a plurality of second subpixels Sp-2 alternately arranged along a column direction. A respective one of the plurality of second columns of subpixels is formed to include a plurality of third subpixels Sp-3 and a plurality of auxiliary subpixels Asp alternately arranged along the column direction. Optionally, a respective one of the plurality of auxiliary subpixels Asp in a respective one of the plurality of second columns of subpixels is formed to be aligned with an inter-subpixel region between a respective one of the plurality of first subpixels Sp-1 and a respective one of the plurality of second subpixels Sp-2 in an adjacent column of the plurality of first columns of subpixels

In some embodiments, organic layers of the plurality of light emitting elements are formed using fine metal mask, subsequent to forming the pixel definition layer. Optionally, the unitary cathode layer is formed in an open mask process, the unitary cathode layer so formed is electrically connected to the plurality of second auxiliary cathodes respectively in the plurality of auxiliary subpixels.

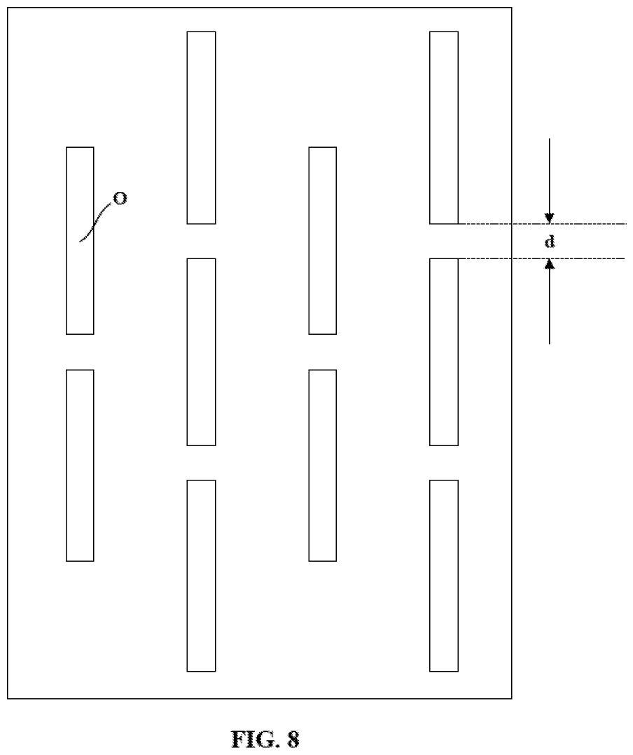

FIG. 8 illustrates a mask plate for forming a plurality of subpixels in some embodiments according to the present disclosure. Referring to FIG. 8, the mask plate in some embodiments is a fine metal mask plate for forming a plurality of third subpixels Sp-3 (e.g., blue subpixels) of the display substrate. For example, the mask plate may be used for depositing a light emitting layer of the plurality of third subpixels Sp-3. As shown in FIGS. 6 to 8, two adjacent third subpixels of the plurality of third subpixels Sp-3 along a column direction may be formed using one opening O in the mask plate. To ensure a clean deposition process, a distance d between two adjacent openings along the column direction can be set above a threshold value. Optionally, d≥40 μm. The space between the two adjacent openings along the column direction can be reserved for forming a respective one of the plurality of auxiliary subpixels Asp.

In another aspect, the present disclosure provides a display apparatus including a display substrate described herein or fabricated by a method described herein, and one or more integrated circuits connected to the display substrate. Optionally, the display apparatus includes a display panel. Optionally, the display panel includes the display substrate described herein or fabricated by a method described herein, and a counter substrate. Examples of appropriate display apparatuses include, but are not limited to, an electronic paper, a mobile phone, a tablet computer, a television, a monitor, a notebook computer, a digital album, a UPS, etc. Optionally, the display apparatus further includes one or more integrated circuits connected to the display panel.

The foregoing description of the embodiments of the invention has been presented for purposes of illustration and description. It is not intended to be exhaustive or to limit the invention to the precise form or to exemplary embodiments disclosed. Accordingly, the foregoing description should be regarded as illustrative rather than restrictive. Obviously, many modifications and variations will be apparent to practitioners skilled in this art. The embodiments are chosen and described in order to explain the principles of the invention and its best mode practical application, thereby to enable persons skilled in the art to understand the invention for various embodiments and with various modifications as are suited to the particular use or implementation contemplated. It is intended that the scope of the invention be defined by the claims appended hereto and their equivalents in which all terms are meant in their broadest reasonable sense unless otherwise indicated. Therefore, the term “the invention”, “the present invention” or the like does not necessarily limit the claim scope to a specific embodiment, and the reference to exemplary embodiments of the invention does not imply a limitation on the invention, and no such limitation is to be inferred. The invention is limited only by the spirit and scope of the appended claims Moreover, these claims may refer to use “first”, “second”, etc. following with noun or element Such terms should be understood as a nomenclature and should not be construed as giving the limitation on the number of the elements modified by such nomenclature unless specific number has been given. Any advantages and benefits described may not apply to all embodiments of the invention. It should be appreciated that variations may be made in the embodiments described by persons skilled in the art without departing from the scope of the present invention as defined by the following claims Moreover, no element and component in the present disclosure is intended to be dedicated to the public regardless of whether the element or component is explicitly recited in the following claims.

1. A display substrate, comprising:
a plurality of subpixels configured to emit light for image display; and
a plurality of auxiliary subpixels that are not light emitting;
wherein the display substrate in a region of the plurality of subpixels comprises:
a base substrate;
a plurality of thin film transistors respectively in the plurality of subpixels and on the base substrate; and
a plurality of light emitting elements respectively in the plurality of subpixels and on a side of the plurality of thin film transistors away from the base substrate, the plurality of light emitting elements being respectively electrically connected to the plurality of thin film transistors;
wherein the display substrate in a region of the plurality of auxiliary subpixels comprises:
a first auxiliary electrode layer on the base substrate and comprising a plurality of first auxiliary cathodes respectively in the plurality of auxiliary subpixels; and
a first insulating layer on a side of the first auxiliary electrode layer away from the base substrate;
a second auxiliary electrode layer comprising a plurality of second auxiliary cathodes respectively in the plurality of auxiliary subpixels, the second auxiliary electrode layer being on a side of the first insulating layer away from the first auxiliary electrode layer;
wherein a respective one of the plurality of first auxiliary cathodes and a respective one of the plurality of second auxiliary cathodes are electrically connected to a unitary cathode layer of the plurality of light emitting elements.

2. The display substrate of claim 1, further comprising
an anode layer on a side of the first insulating layer away from the base substrate;
wherein the anode layer comprises a plurality of anodes, a respective one of the plurality of anodes being in a respective one of the plurality of light emitting elements.

3. The display substrate of claim 2, wherein the second auxiliary electrode layer and the anode layer are in a same layer and comprise a same material; and
the respective one of the plurality of second auxiliary cathodes electrically connects the respective one of the plurality of first auxiliary cathodes to the unitary cathode layer of the plurality of light emitting elements.

4. The display substrate of claim 3, wherein the respective one of the plurality of second auxiliary cathodes extends through the first insulating layer to electrically connect to the respective one of the plurality of first auxiliary cathodes in a respective one of the plurality of auxiliary subpixels; and
an orthographic projection of the respective one of the plurality of second auxiliary cathodes on the base substrate at least partially overlaps with an orthographic projection of the respective one of the plurality of first auxiliary cathodes on the base substrate.

5. The display substrate of claim 4, further comprising a pixel definition layer for defining a plurality of subpixel apertures respectively in the plurality of subpixels and a plurality of auxiliary subpixel apertures respectively in the plurality of auxiliary subpixels.

6. The display substrate of claim 5, wherein the unitary cathode layer extends into a respective one of the plurality of auxiliary subpixel apertures to connect to the respective one of the plurality of second auxiliary cathodes.

7. The display substrate of claim 5, further comprising an organic functional layer between the anode layer and the unitary cathode layer and in the plurality of subpixel apertures;
wherein the organic functional layer is absent in the plurality of auxiliary subpixel apertures.

8. The display substrate of claim 1, further comprising a source-drain electrode layer comprising a plurality of source electrodes respectively for the plurality of thin film transistors and a plurality of drain electrodes respectively for the plurality of thin film transistors; and
a second insulating layer on a side of the source-drain electrode layer away from the base substrate;
wherein the first auxiliary electrode layer is on a side of the second insulating layer away from the source-drain electrode layer.

9. The display substrate of claim 1, further comprising a source-drain electrode layer comprising a plurality of source electrodes respectively for the plurality of thin film transistors and a plurality of drain electrodes respectively for the plurality of thin film transistors;
wherein the first auxiliary electrode layer and the source-drain electrode layer are in a same layer and comprise a same material.

10. The display substrate of claim 1, wherein the first auxiliary electrode layer comprises a metallic material.

11. The display substrate of claim 3, wherein the second auxiliary electrode layer and the anode layer comprise an oxide semiconductor material; and
the first auxiliary electrode layer comprises a metallic material.

12. The display substrate of claim 1, wherein the plurality of auxiliary subpixels are absent of any light emitting elements and thin film transistors.

13. The display substrate of claim 1, wherein the display substrate comprises a plurality of pixels, a respective one of the plurality of pixels comprising a respective one of a plurality of first subpixels, a respective one of a plurality of second subpixels, a respective one of a plurality of third subpixels, and a respective one of the plurality of auxiliary subpixels;
the plurality of subpixels are arranged as a plurality of first columns of subpixels and a plurality of second columns of subpixels alternately arranged along a row direction;
a respective one of the plurality of first columns of subpixels comprises a plurality of first subpixels and a plurality of second subpixels alternately arranged along a column direction;
a respective one of the plurality of second columns of subpixels comprises a plurality of third subpixels and a plurality of auxiliary subpixels alternately arranged along the column direction; and
a respective one of the plurality of auxiliary subpixels in a respective one of the plurality of second columns of subpixels is aligned, along the row direction, with an inter-subpixel region between a respective one of the plurality of first subpixels and a respective one of the plurality of second subpixels in an adjacent column of the plurality of first columns of sub pixels.

14. A display apparatus, comprising the display substrate of claim 1, and one or more integrated circuits connected to the display substrate.

15. A method of fabricating a display substrate, comprising:
forming a plurality of subpixels configured to emit light for image display; and
forming a plurality of auxiliary subpixels that are not light emitting;
wherein forming the plurality of subpixels comprises:
forming a plurality of thin film transistors respectively in the plurality of subpixels and on a base substrate; and
forming a plurality of light emitting elements respectively in the plurality of subpixels and on a side of the plurality of thin film transistors away from the base substrate, the plurality of light emitting elements formed to be respectively electrically connected to the plurality of thin film transistors;
wherein forming the plurality of auxiliary subpixels comprises:
forming a first auxiliary electrode layer on the base substrate, the first auxiliary electrode layer formed to comprise a plurality of first auxiliary cathodes respectively in the plurality of auxiliary subpixels; and
forming a first insulating layer on a side of the first auxiliary electrode layer away from the base substrate;
forming a second auxiliary electrode layer comprising a plurality of second auxiliary cathodes respectively in the plurality of auxiliary subpixels, the second auxiliary electrode layer formed on a side of the first insulating layer away from the first auxiliary electrode layer;
wherein a respective one of the plurality of first auxiliary cathodes and a respective one of the plurality of second auxiliary cathodes are formed to be electrically connected to a unitary cathode layer of the plurality of light emitting elements.

16. The method of claim 15, subsequent to forming the plurality of thin film transistors, further comprising:
forming an anode layer on a side of the first insulating layer away from the base substrate;
wherein forming the anode layer comprises forming a plurality of anodes, a respective one of the plurality of anodes formed in a respective one of the plurality of light emitting elements.

17. The method of claim 16, wherein the second auxiliary electrode layer and the anode layer are formed in a same layer and using a same material in a same patterning process with a same mask plate; and
a respective one of the plurality of second auxiliary cathodes is formed to electrically connects the respective one of the plurality of first auxiliary cathodes to the unitary cathode layer of the plurality of light emitting elements.

18. The method of claim 17, further comprising forming a pixel definition layer for defining a plurality of subpixel apertures respectively in the plurality of subpixels and a plurality of auxiliary subpixel apertures respectively in the plurality of auxiliary subpixels.

19. The method of claim 18, subsequent to forming the pixel definition layer, further comprising:
depositing an organic material layer in the plurality of subpixel apertures and in the plurality of auxiliary subpixel apertures; and
ashing the organic material layer in the plurality of auxiliary subpixel apertures to completely remove any organic functional material therein to expose the plurality of second auxiliary cathodes.

20. The method of claim 19, subsequent to ashing the organic material layer in the plurality of auxiliary subpixel apertures, further comprising depositing a conductive material layer in an open mask process, thereby forming the unitary cathode layer.
